(19) United States
(12) Patent Application Publication
(10) Pub. No.: US 2012/0280262 A1
(43) Pub. Date: Nov. 8, 2012

(54) SEMICONDUCTOR LIGHT EMITTING DEVICE AND METHOD FOR MANUFACTURING THEREOF

(75) Inventor: HSIN-CHIANG LIN, Hukou (TW)

(73) Assignee: ADVANCED OPTOELECTRONIC TECHNOLOGY, INC., Hsinchu Hsien (TW)

(21) Appl. No.: 13/301,706

(22) Filed: Nov. 21, 2011

(30) Foreign Application Priority Data
May 6, 2011 (CN) 201110116716.4

(51) Int. Cl. H01L 33/44

(52) U.S. Cl. 257/98; 438/27; 257/E33.061

(57) ABSTRACT

A semiconductor light emitting device comprises a circuit, a reflector, an LED chip, an encapsulation layer and a luminescent conversion layer. The encapsulation layer comprises an annular projection formed outside the encapsulation layer. The circuit and the LED chip are covered by the encapsulation layer, wherein the annular projection of the encapsulation layer is inside the reflector; the encapsulation layer also fills in an interspace between two electrodes of the circuit. Therefore the semiconductor light emitting device is rigid and strongly resistant to water vapor and similar contaminants.

### TECHNICAL FIELD

The disclosure relates generally to semiconductor devices, and more particularly to a semiconductor light emitting device.

### DESCRIPTION OF THE RELATED ART

Light emitting diodes (LEDs) are popular due to their low power consumption, high efficiency, quick reaction time, long life and the absence of toxic elements such as mercury in their manufacture. For further increasing the light emitting efficiency of a LED device, a reflector is placed around a LED chip to centralize the light emitted from the LED chip in a certain direction. The reflector may be located on electrodes where the LED chip is disposed thereon. The electrodes may be composed of metal and the reflector may be made of plastic such as Polyphthalamide (PPA) or Polymethyl-methacrylate (PMMA). However, these two materials adhere poorly to each other; therefore vapor or moisture may permeate into the LED device that renders the LED device less efficient or even nonfunctioning. To avoid these limitations, a semiconductor light emitting device with a better water proofing ability is required.

### BRIEF DESCRIPTION OF THE DRAWINGS

FIG. 1 is a cross section of a semiconductor light emitting device of the disclosure.

FIG. 2 is a flow chart of a method for manufacturing the semiconductor light emitting device of FIG. 1.

FIG. 3 is a cross section of a step in forming an encapsulation layer in accordance with FIG. 2.

FIG. 4 is a cross section of a step in forming a reflector in accordance with FIG. 2.

FIG. 5 is a cross section of a step in forming a luminescent conversion layer in accordance with FIG. 2.

### DETAILED DESCRIPTION

Exemplary embodiments of the disclosure will be described with reference to the accompanying drawings.

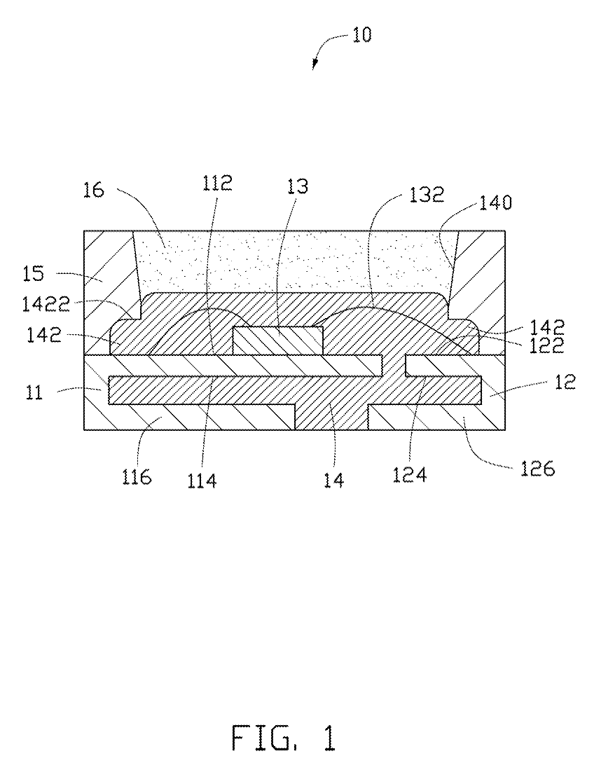

Referring to FIG. 1, the disclosure provides a semiconductor light emitting device 10 comprising a circuit (not labeled) having a first electrode 11 and a second electrode 12, a LED chip 13, an encapsulation layer 14, a reflector 15 and a luminescent conversion layer 16. The circuit comprises a top surface and a bottom surface opposite to each other, wherein the first electrode 11 comprises a top face 112 and a bottom face 114, and the second electrode 12 comprises a top face 122 and a bottom face 124. The first electrode 11 and the second electrode 12 are separated.

In this embodiment, the LED chip 13 is located on the top face 112 of the first electrode 11 and is electrically connected to the first and the second electrodes 11, 12 via conductive wires 132. Alternatively, the connection can also be achieved by flip chip or eutectic (not shown). Moreover, a first extending portion 116 of the first electrode 11 is bent and extends from the top surface of the circuit to the bottom surface of the circuit. Similarly, a second extending portion 126 of the second electrode 12 is bent and extends from the top surface of the circuit to the bottom surface of the circuit. Accordingly, the semiconductor light emitting device 10 is constructed as a surface mount device (SMD) so as to be installed conveniently.

The encapsulation layer 14 involves the LED chip 13 and a portion of the circuit in which the top faces 112, 122 and the bottom faces 114, 124 of the first electrode 11 and the second electrode 12 are included. The encapsulation layer 14 comprises an annular projection 142 formed on the lateral side of the encapsulation layer 14 and disposed on the top faces 112, 122 of the first and second electrodes 11, 12. A portion (not labeled) of the encapsulation layer 14 is exposed on the base of the semiconductor light emitting device 10. In this embodiment, the annular projection 142 is inserted inside the reflector 15 and is sandwiched between the circuit and the reflector 15, such that the encapsulation layer 14 is divided into a top portion upon the top surface of the circuit and a bottom portion below the top surface of the circuit. In the disclosure, the encapsulation layer 14 is transparent material made of epoxy, silicone or a hybrid thereof. Moreover, the LED chip 13 and the connections between the LED chip 13 and the circuit are covered by the encapsulation layer 14, and inner faces of the first and second electrodes 11, 12 are entirely covered by encapsulation layer 14 since the encapsulation layer 14 also fills in the interspace between the first and second electrodes 11, 12, whereby the electrical properties of the semiconductor light emitting device 10 are protected. Further, the semiconductor light emitting device 10 can be made rigid and extremely vapor-proof

The reflector 15 located on the top surface of the circuit and in the top surface 1422 of the annular projection 142 a depression 140 is defined, by which to increase the light emitting efficiency of the semiconductor light emitting device 10. Accordingly, the LED chip 13 is located inside the depression 140 and surrounded by the reflector 15. The reflector 15 is made of reflective material such as Polyphthalamide (PPA) or plastic.

The luminescent conversion layer 16 is located on the encapsulation layer 14 and is surrounded by the reflector 15. Alternatively, the luminescent conversion layer 16 may incorporate at least one luminescent element (not labeled), and the luminescent conversion layer 16 can be made of epoxy, silicone or a hybrid thereof In one embodiment, the refraction index of the luminescent conversion layer 16 is less than that of the encapsulation layer 14, such that light emitted from the LED chip 13 outside the semiconductor light emitting device 10 can be extracted preferably in accordance with Snell's Law.

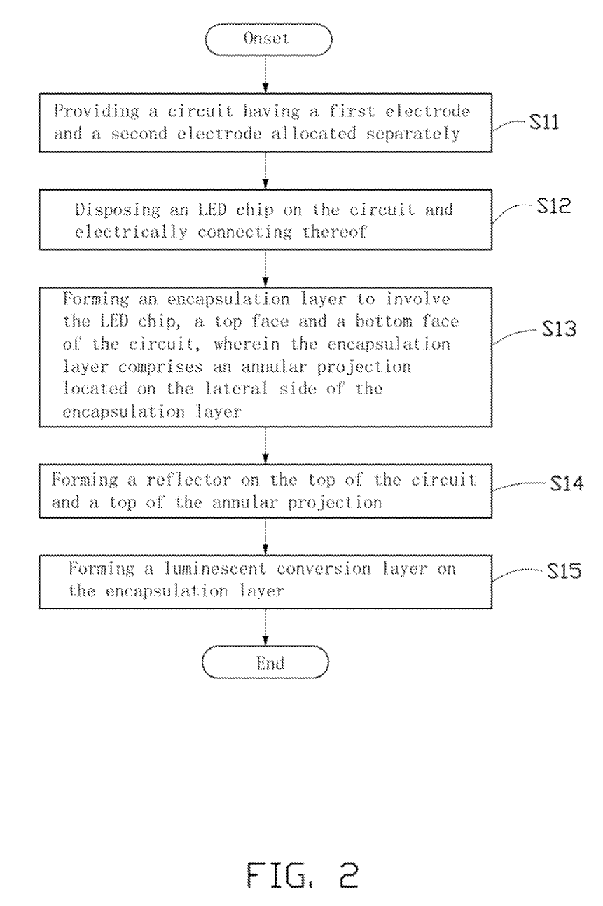

Referring to FIG. 2, a method for manufacturing the semiconductor light emitting device 10 is provided as follows:

In step S11, a circuit having a first electrode 11 and a separate second electrode 12 is provided.

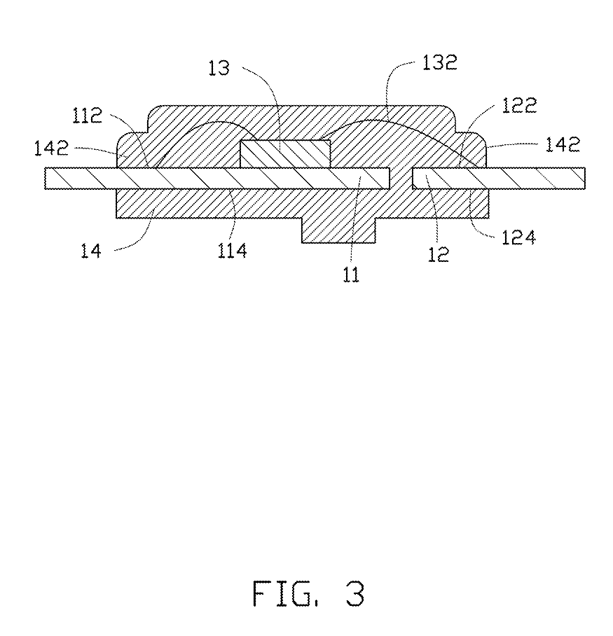

In step S12, an LED chip 13 is disposed on the circuit and electrically connected thereto. As shown in FIG. 3, the LED chip 13 is disposed on a top face 112 of the first electrode 11 and is electrically connected to the first and second electrodes 11, 12 via conductive wires 132. Alternatively, the connections can also be made by flip chip or eutectic.

In step S13, an encapsulation layer 14 is formed to enclose the LED chip 13 and the top surface of the circuit. Furthermore, the encapsulation 14 fills in an interspace between the first and second electrodes 11, 12. Specifically, the encapsulation layer 14 covers the top faces 112, 122 and the bottom faces 114, 124 of the first and the second electrodes 11, 12. The encapsulation layer 14 comprises an annular projection 142 located on the lateral side of the encapsulation layer 14. In this embodiment, the encapsulation layer 14 is made by a molding process.

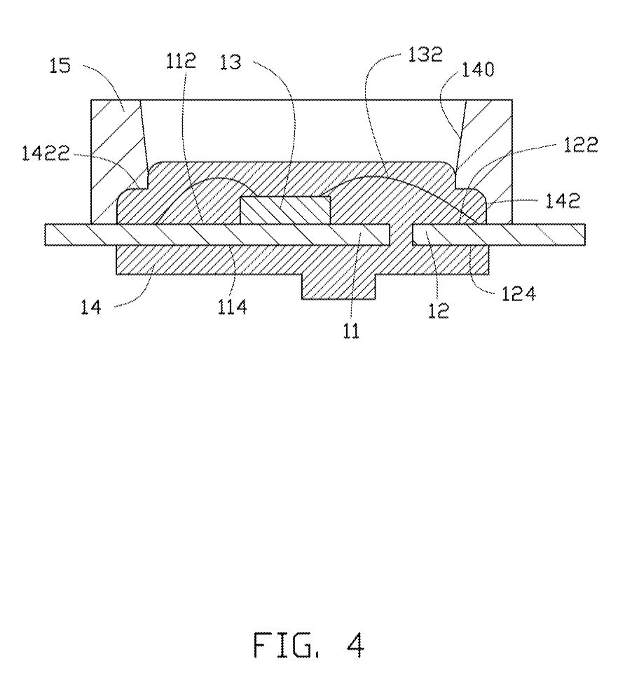

In step S14, a reflector 15 is formed on the top surface of the circuit and the top surface 1422 of the annular projection 142, as shown in FIG. 4. The reflector 15 defines a depression 140 on the circuit around the encapsulation layer 14. Specifically, the encapsulation layer 14 is sandwiched between the reflector 15 and the circuit. In this embodiment, the reflector 15 is formed by a molding process.

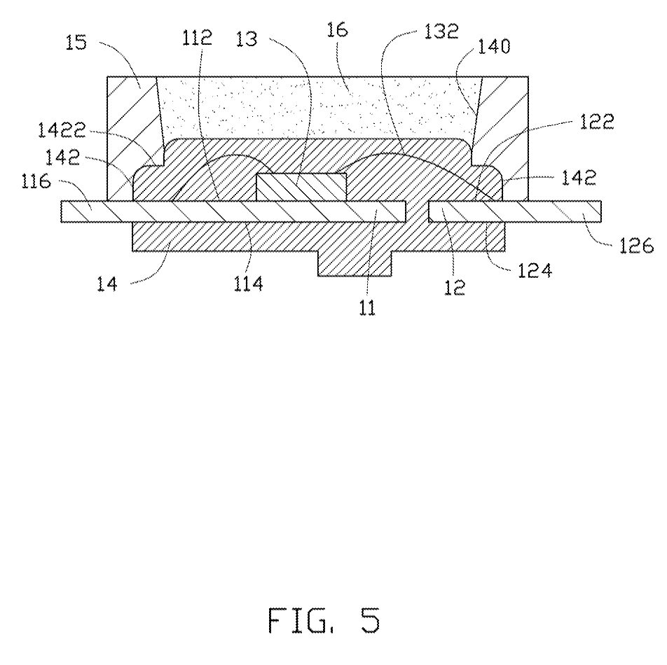

In step S15 (as shown in FIG. 5), a luminescent conversion layer 16 is formed on the encapsulation layer 14 and surrounded by the reflector 15. Alternatively, the luminescent conversion layer 16 incorporates at least one luminescent element, and the luminescent conversion layer can be made of epoxy, silicone or a hybrid thereof via an injection molding process.

In this embodiment (as shown in FIG. 1), a first extending portion 116 of the first electrode 11 is bent and extends from the top surface of the circuit to the bottom surface of the circuit. Similarly, a second extending portion 126 of the second electrode 12 is bent and extends from the top surface of the circuit to the bottom surface of the circuit. Accordingly, the semiconductor light emitting device 10 is a surface mount device (SMD).

The connections between the LED chip 13 and the relevant areas of the circuit are covered by the encapsulation layer 14, thereby for protecting and sealing all the electrical properties of the semiconductor light emitting device 10. In the disclosure, the encapsulation layer 14 is made of epoxy material or silicone resin which has a better adhesion to the circuit than that of a reflector made of PPA or plastic. Moreover, the inner faces of the first and second electrodes 11, 12 are entirely covered by the encapsulation layer 14; therefore, the semiconductor light emitting device 10 is rigid with (effectively) a one-piece construction, and is strongly resistant to vapor and similar contaminants. Further, in the manufacturing process of the semiconductor light emitting device 10, the encapsulation layer 14, the reflector 15 and the luminescent conversion layer 16 can be formed by molding processes which can be very easily adapted to mass production.

It is to be understood, however, that even though numerous characteristics and advantages of the disclosure have been set forth in the foregoing description, together with details of the structure and function of the disclosure, the disclosure is illustrative only, and changes may be made in detail, especially in the matters of shape, size, and arrangement of parts within the principles of the disclosure to the full extent indicated by the broad general meaning of the terms in which the appended claims are expressed.

What is claimed is:

1. A semiconductor light emitting device, comprising:
a circuit, having a first electrode and a separate second electrode;
a reflector, located on the circuit and defining a depression on the circuit;
an LED chip, located on the circuit and being electrically connected thereto, wherein the LED chip is located inside the depression and is surrounded by the reflector;
an encapsulation layer, involving the LED chip and the circuit, comprising an annular projection formed on the lateral side of the encapsulation layer and being incorporated inside the reflector; and
a luminescent conversion layer, located on the encapsulation layer.

2. The semiconductor light emitting device as claimed in claim 1, wherein the first electrode and the second electrode respectively comprise a top face and a bottom face opposite to each other.

3. The semiconductor light emitting device as claimed in claim 2, wherein the LED chip is disposed on the top face of the first electrode and is electrically connected to the first and second electrodes via conductive wires.

4. The semiconductor light emitting device as claimed in claim 1, wherein a first extending portion of the first electrode and a second extending portion of the second electrode are bent and, respectively, extend from a top surface of the circuit to a bottom surface of the circuit so that the semiconductor light emitting device is a surface mounting device.

5. The semiconductor light emitting device as claimed in claim 4, wherein a portion of the encapsulation layer is exposed to a base of the semiconductor light emitting device.

6. The semiconductor light emitting device as claimed in claim 2, wherein the annular projection is located on the top faces of the first and second electrodes.

7. The semiconductor light emitting device as claimed in claim 2, wherein the top faces and the bottom faces of the first and the second electrodes are involved into the encapsulation layer.

8. The semiconductor light emitting device as claimed in claim 1, wherein the encapsulation is transparent made of epoxy, silicone or hybrid thereof

9. The semiconductor light emitting device as claimed in claim 1, wherein the reflector is reflective made of Polyphthalamide (PPA) or plastic.

10. The semiconductor light emitting device as claimed in claim 1, wherein the luminescent conversion layer comprises at least one luminescent element, and the luminescent conversion layer is made of epoxy, silicone or hybrid thereof

11. The semiconductor light emitting device as claimed in claim 1, wherein a refraction index of the luminescent conversion layer is less than that of the encapsulation layer.

12. A method for manufacturing a semiconductor light emitting device, comprising:
providing a circuit having a first electrode and a separate second electrode;
disposing an LED chip on the circuit and electrically connecting thereto;
forming an encapsulation layer to enclose the LED chip, a top surface of the circuit and an interspace between the first and second electrodes, wherein the encapsulation layer comprises an annular projection formed on a lateral side of the encapsulation layer;
forming a reflector on the top surface of the circuit and a top surface of the annular projection; and
forming a luminescent conversion layer on the encapsulation layer.

13. The method for manufacturing the semiconductor light emitting device as claimed in claim 12, wherein the first and the second electrodes are bent and, respectively, extends to a base of the semiconductor light emitting device so that the semiconductor light emitting device is a surface mounting device.

14. The method for manufacturing the semiconductor light emitting device as claimed in claim 12, wherein the encapsulation layer is formed by a molding process.

15. The method for manufacturing the semiconductor light emitting device as claimed in claim 12, wherein the encapsulation layer comprises a top portion upon the top surface of the circuit and a bottom portion below the top surface of the circuit.

16. The method for manufacturing the semiconductor light emitting device as claimed in claim 12, wherein the reflector is formed by a molding process.

17. The method for manufacturing the semiconductor light emitting device as claimed in claim 12, wherein the reflector is located around the encapsulation layer and defines a depression located on the top surface of the circuit, the annular projection being fitted in the depression.

18. The method for manufacturing the semiconductor light emitting device as claimed in claim 12, wherein the luminescent conversion layer is formed by a molding process.
